(19) United States
(12) Patent Application Publication
(10) Pub. No.: US 2026/0136937 A1
(43) Pub. Date: May 14, 2026

(54) SEMICONDUCTOR PACKAGE

(71) Applicant: Samsung Electronics Co., Ltd., Suwon-si (KR)

(72) Inventors: Sangho SHIN, Suwon-si (KR); Sungeun KIM, Suwon-si (KR); Hae-Jung YU, Suwon-si (KR); Yanggyoo JUNG, Suwon-si (KR)

(73) Assignee: Samsung Electronics Co., Ltd., Suwon-si (KR)

(21) Appl. No.: 19/221,715

(22) Filed: May 29, 2025

(30) Foreign Application Priority Data
Nov. 11, 2024 (KR) 10-2024-0159606

(51) Int. Cl. H01L 23/00; H01L 25/16

(52) U.S. Cl. CPC H10W 42/121; H10W 90/00; H10W 74/15; H10W 90/724; H10W 90/734

(57) ABSTRACT

A semiconductor package includes a substrate, a semiconductor chip and a shielding structure on the substrate, and a connection terminal between the substrate and the semiconductor chip. The shielding structure is disposed on a side surface of the semiconductor chip. A level of an upper surface of the shielding structure is disposed between a lower surface of the semiconductor chip and an upper surface of the semiconductor chip. A melting point of the shielding structure is higher than a melting point of the connection terminal.

### CROSS-REFERENCE TO RELATED APPLICATIONS

This U.S. non-provisional patent application claims priority under 35 U.S.C. § 119 to Korean Patent Application No. 10-2024-0159606 filed on Nov. 11, 2024, in the Korean Intellectual Property Office, the entire contents of which are hereby incorporated by reference.

### BACKGROUND

The present disclosure relates to a semiconductor packages, and more specifically, relates to semiconductor packages including a shielding structure.

Recently, the demand for mobile devices has rapidly increased in the electronic device markets. Accordingly, there is an ongoing demand for electronic components mounted in mobile devices for miniaturization and/or lightweight. In order to satisfy this demand, not only technology for reducing respective sizes of mounted components but also semiconductor packaging technology for integrating a larger number of mounted components into a single package is desired. In particular, a semiconductor package in which a plurality of elements are integrated is desired for miniaturization as well as to have improved bending characteristics, heat dissipation characteristics, and/or electrical characteristics.

### SUMMARY

Some example embodiments of the inventive concepts provide semiconductor packages with improved structural stability and/or reliability and/or methods of manufacturing the same.

The problems to be solved by the inventive concepts are not limited to the problems mentioned above, and other problems not mentioned may be clearly understood by those skilled in the art from the description below.

A semiconductor package according to an example embodiment of the inventive concepts includes a substrate, a semiconductor chip and a shielding structure on the substrate, and a connection terminal between the substrate and the semiconductor chip, wherein the shielding structure is on a side surface of the semiconductor chip, a level of an upper surface of the shielding structure is between a lower surface of the semiconductor chip and an upper surface of the semiconductor chip, and a melting point of the shielding structure is higher than a melting point of the connection terminal.

A semiconductor package according to an example embodiment of the inventive concepts includes a substrate and a semiconductor chip and a plurality of shielding structures on the substrate, wherein the semiconductor chip has four side surfaces connected to each other, and two adjacent side surfaces of the four side surfaces form corner portions, a side surface of each of the shielding structures have an inclined portion, and the shielding structures are at least one pair, and the pair of the shielding structures is adjacent to each other based on the corner portion.

A semiconductor package according to an example embodiment of the inventive concepts includes a package substrate, an interposer substrate on the package substrate, a chip stack, a semiconductor chip, and first and second shielding structures on the interposer substrate, and connection terminals between the interposer substrate and the chip stack and between the interposer substrate and the semiconductor chip, wherein the semiconductor chip and the chip stack are spaced apart in a first direction parallel to an upper surface of the package substrate, the first shielding structure is on a side surface of the chip stack, the second shielding structure is on a side surface of the semiconductor chip, a height of the first and second shielding structures is greater than a height of the connection terminals, the first and second shielding structures include a first metal material and a second metal material, the first metal material includes at least one of silver or copper, the second metal material is tin, in the first and second shielding structures, a content of the first metal material is 70 wt % to 97 wt % based on 100 wt % of the first and second shielding structures, and a content of the second metal material is 3 wt % to 30 wt % based on 100 wt % of the first and second shielding structures.

A method of manufacturing a semiconductor package according to an example embodiment includes providing a substrate, exposing a first group of spaces using a first mask pattern, forming a plurality of preliminary connection terminals in the first group of spaces, removing the first mask pattern and forming a second mask pattern to expose a second group of spaces, forming a plurality of shielding structures in the second group of spaces, removing the second mask pattern, mounting a semiconductor chip structure on the preliminary connection terminals at an area including the first group of spaces such that a plurality of chip pads on a lower surface of the semiconductor chip structure are in contact with the preliminary connection terminals and the semiconductor chip structure is confined by the shielding structures, and performing a reflow process on the preliminary connection terminals at a temperature higher than a melting point of the preliminary connection terminals and lower than a melting point of the shielding structures to deforming the preliminary connection terminals to form a plurality of connection terminals.

The forming the plurality of shielding structures may include forming the shielding structures such that an upper surface thereof is between a lower surface and an upper surface of the semiconductor chip structure.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a plan view of a semiconductor package according to an example embodiment of the inventive concepts.

FIG. 2 is a cross-sectional view taken along line A-A′ of FIG. 1.

FIG. 3 is an enlarged view of portion ‘CU’ of FIG. 2.

FIG. 4 is a plan view of a semiconductor package according to an example embodiment of the inventive concepts.

FIG. 5 is a plan view of a semiconductor package according to an example embodiment of the inventive concepts.

FIGS. 6, 7, 8, 9, and 10 are cross-sectional views illustrating a manufacturing process of a semiconductor package according to an example embodiment of the inventive concepts.

### DETAILED DESCRIPTION

Hereinafter, the inventive concepts will be described in detail by describing some example embodiments of the inventive concepts with reference to the attached drawings.

As used herein, expressions such as “one of,” “one or more of,” “any one of,” and “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., +10%).

When the term “about,” “substantially” or “approximately” is used in this specification in connection with a numerical value, it is intended that the associated numerical value includes a manufacturing or operational tolerance (e.g., +10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes.

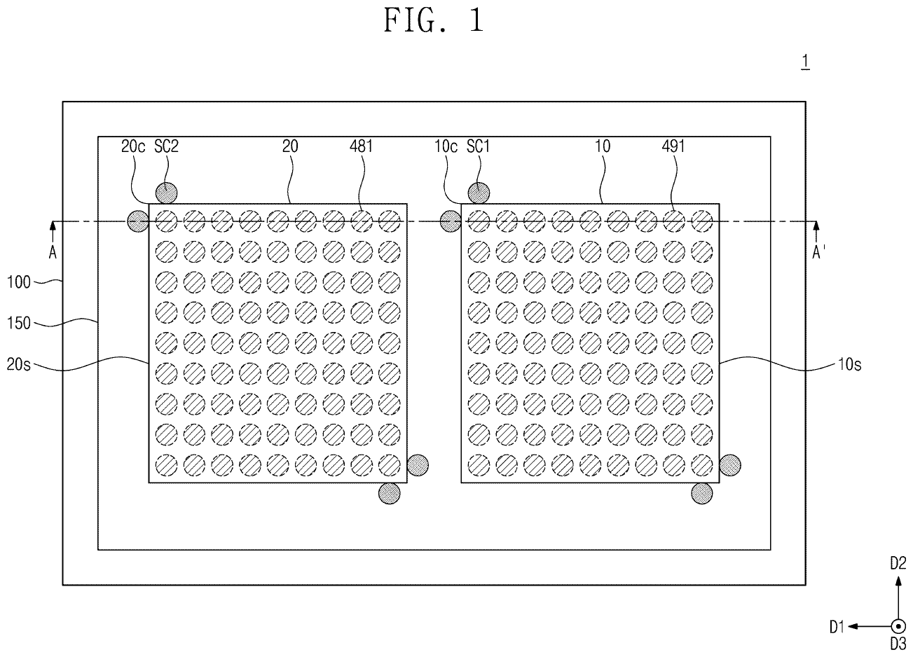

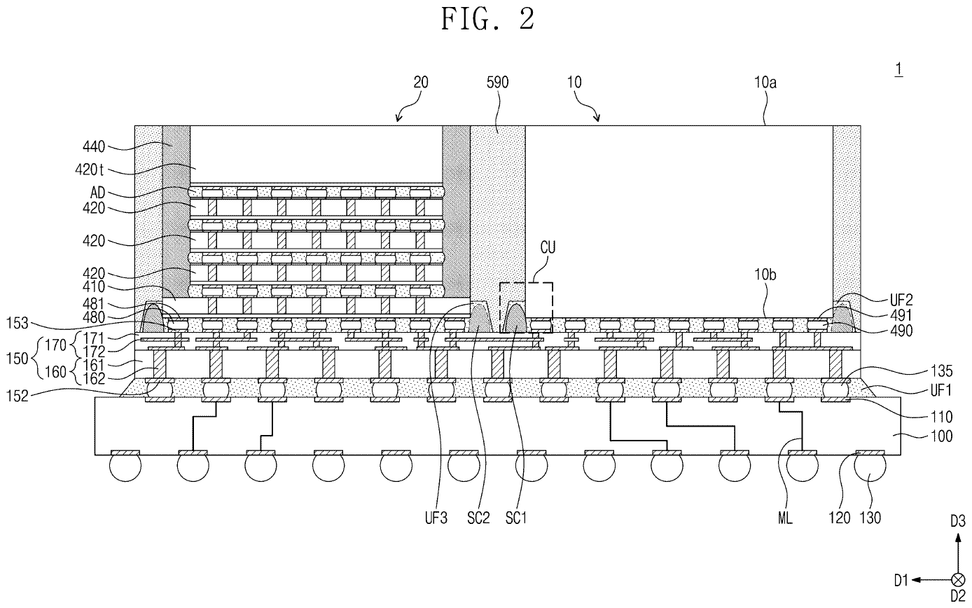

FIG. 1 is a plan view of a semiconductor package according to an example embodiment of the inventive concepts. FIG. 2 is a cross-sectional view taken along line A-A′ of FIG. 1.

Referring to FIGS. 1 and 2, a semiconductor package according to an example embodiment of the inventive concepts may include a package substrate 100, an interposer substrate 150, a first semiconductor chip 10, a chip structure 20, a first shielding structure SC1, and a second shielding structure SC2. The semiconductor chip 10 and the chip structure 20, individually or collectively, may be referred to as a semiconductor chip structure.

The package substrate 100 may be, for example, a printed circuit board (PCB). In some example embodiments, although not shown, the package substrate 100 may have a structure in which an insulating layer and a wiring layer are alternately stacked. The package substrate 100 may include a plurality of first substrate pads 110 on an upper surface, a plurality of second substrate pads 120 on a lower surface, and metal wirings ML.

External connection terminals 130 may be disposed on the second substrate pads 120, respectively. The external connection terminals 130 may be electrically connected to the wiring layer in the package substrate 100 and the first substrate pads 110 through the second substrate pads 120.

The external connection terminals 130 may include solder balls or solder bumps. Depending on the type and arrangement of the external connection terminals 130, the external connection terminals may be provided in a form of a ball grid array (BGA), a fine ball-grid array (FBGA), or a land grid array (LGA). The external connection terminals 130 may be an alloy including at least one of silver, copper, or tin.

The interposer substrate 150 may be disposed on the package substrate 100. The interposer substrate 150 may include an interposer core layer 160 and an interposer wiring layer 170. The interposer core layer 160 may include a core substrate 161 and interposer vias 162 that vertically penetrate the core substrate 161. The core substrate 161 may be a semiconductor substrate, and as an example, the core substrate 161 may be a silicon (Si) substrate. A plurality of interposer vias 162 may be provided in a first direction D1.

In this specification, the first direction D1 is defined as a direction parallel to an upper surface of the package substrate 100. A second direction D2 is defined as a direction parallel to the upper surface of the package substrate 100 and perpendicular to the first direction D1. A third direction D3 is defined as a direction perpendicular to the upper surface of the package substrate 100.

The interposer wiring layer 170 may be disposed on the interposer core layer 160. That is, the interposer core layer 160 may be disposed closer to the package substrate 100 than the interposer wiring layer 170. The interposer wiring layer 170 may include an interposer insulating layer 171 and wiring patterns 172 in the interposer insulating layer 171. The wiring patterns 172 may be electrically connected to the interposer vias 162. The interposer insulating layer 171 may include an insulating material such as silicon oxide and silicon nitride. The wiring patterns 172 may include a metal material such as copper.

Upper interposer pads 153 may be disposed on an upper surface of the interposer substrate 150. Lower interposer pads 152 may be disposed on a lower surface of the interposer substrate 150. The upper interposer pads 153 may be exposed from the upper surface of the interposer substrate 150. The lower interposer pads 152 may be exposed from the lower surface of the interposer substrate 150.

First connection terminals 135 may be disposed between the package substrate 100 and the interposer substrate 150. For example, each of the first connection terminals 135 may be interposed between the lower interposer pads 152 and the first substrate pads 110 and may come into contact with the lower interposer pads 152 and the first substrate pads 110. The first connection terminals 135 may include a metal material substantially the same as or similar to the external connection terminal 130. For example, the first connection terminals 135 may be an alloy including at least one of tin (Sn), silver (Ag), or copper (Cu).

A first underfill layer UF1 may be provided between the package substrate 100 and the interposer substrate 150. The first underfill layer UF1 may fill a space between the package substrate 100 and the interposer substrate 150 and may surround a side surface of each of the first connection terminals 135. The first underfill layer UF1 may include, for example, an epoxy resin.

The first semiconductor chip 10 may be disposed on the interposer substrate 150. The first semiconductor chip 10 may include a graphic processing unit (GPU) die, a central processing unit (CPU) die, or a system on chip (SoC). For example, the first semiconductor chip 10 may be a logic chip.

First chip pads 491 may be disposed on a lower surface of the first semiconductor chip 10. Second connection terminals 490 may be disposed between the first semiconductor chip 10 and the interposer substrate 150. For example, the second connection terminals 490 may be interposed between the first chip pads 491 and the upper interposer pads 153 and may be in contact with the first chip pads 491 and the upper interposer pads 153. The first semiconductor chip 10 may be electrically connected to the package substrate 100 through the second connection terminals 490. The second connection terminals 490 may include silver, copper, and/or tin.

A second underfill layer UF2 may be provided between the first semiconductor chip 10 and the interposer substrate 150. The second underfill layer UF2 may fill a space between the first semiconductor chip 10 and the interposer substrate 150 and may surround a side surface of each of the second connection terminals 490. The second underfill layer UF2 may include, for example, an epoxy resin.

The chip structure 20 may be disposed on an interposer substrate 150. In this specification, the chip structure 20 may be described as a chip stack 20 or a high bandwidth memory (HBM) 20. The chip structure 20 may include a second semiconductor chip 410, third semiconductor chips 420 and 420t disposed on the second semiconductor chip 410, and a first molding layer 440. In this specification, the second semiconductor chip 410 may be referred to as a base chip 410, and the third semiconductor chips 420 and 420t may be referred to as memory chips 420 and 420t.

The base chip 410 may be a logic chip. The base chip 410 may be, for example, a memory controller. The memory chips 420 and 420t may be stacked on the base chip 410 in the third direction D3. The memory chips 420 and 420t may be the same type of semiconductor chips having the same circuit. The memory chips 420 and 420t may be either D-RAM or Nand-Flash.

The base chip 410 and the memory chips 420 and 420t may both include circuit layers. The base chip 410 and the memory chips 420 may include through-vias. The memory chip 420t that is disposed at the top of the memory chips 420 and 420t may not include through-vias therein. According to some example embodiments, unlike the illustrated example embodiment, the memory chip 420t disposed at the top may include through-vias. The through-vias of the base chip 410 and the through-vias of the neighboring memory chip 420 may be connected to each other through micro bumps. The through-vias between the neighboring memory chips 420 may be connected to each other through micro bumps.

Adhesive layers AD may be interposed between the base chip 410 and the neighboring memory chip 420, and between the neighboring memory chips 420. The adhesive layers AD may be, for example, a non-conductive film (NCF) including a polymer.

The first molding layer 440 may cover an upper surface of the base chip 410, side surfaces of the memory chips 420 and 420t, and side surfaces of the adhesive layers AD. The upper surface of the uppermost memory chip 420t may be exposed from the first molding layer 440. The first molding layer 440 may include an insulating material such as an epoxy molding compound (EMC).

Second chip pads 481 may be disposed on the lower surface of the chip structure 20. Third connection terminals 480 may be disposed between the chip structure 20 and the interposer substrate 150. For example, the third connection terminals 480 may be interposed between the second chip pads 481 and the upper interposer pads 153 and may be in contact with the second chip pads 481 and the upper interposer pads 153. The chip structure 20 may be electrically connected to the package substrate 100 through the third connection terminals 480. The third connection terminals 480 may include copper and tin.

A third underfill layer UF3 may be provided between the chip structure 20 and the interposer substrate 150. The third underfill layer UF3 may fill a space between the chip structure 20 and the interposer substrate 150 and may surround a side surface of each of the third connection terminals 480. The third underfill layer UF3 may include, for example, an epoxy resin.

The first shielding structure SC1 and the second shielding structure SC2 may be disposed on the upper surface of the interposer substrate 150. FIG. 2 is a cross-sectional view taken along line A-A′ of FIG. 1, but for convenience of explanation, a plurality of first shielding structures SC1 and a plurality of second shielding structures SC2 are illustrated.

The first shielding structures SC1 may be disposed on the side surface of the first semiconductor chip 10. The first shielding structures SC1 may be in contact with the first semiconductor chip 10. The first shielding structures SC1 may be in contact with the second underfill layer UF2. According to one example embodiment, the first shielding structures SC1 may be provided in the second underfill layer UF2. The first shielding structures SC1 may be spaced apart from the upper interposer pads 153 in the first direction D1.

For example, as shown in FIG. 1, the first semiconductor chip 10 may have four side surfaces 10s that are connected to each other when viewed in a plan view. In this case, two adjacent side surfaces 10s among the four side surfaces 10s may form a first corner portion 10c. The first shielding structures SC1 may be paired, and the pair of first shielding structures SC1 may be disposed to be adjacent to each other based on the first corner portion 10c.

The second shielding structures SC2 may be disposed on a side surface of the chip structure 20. The second shielding structures SC2 may be in contact with the chip structure 20. The second shielding structures SC2 may be in contact with the third underfill layer UF3. According to some example embodiments, the second shielding structures SC2 may be provided in the third underfill layer UF3. The second shielding structures SC2 may be spaced apart from the upper interposer pads 153 in the first direction D1.

The chip structure 20 may have four side surfaces 20s connected to each other when viewed in a plan view. In this case, two adjacent side surfaces 20s among the four side surfaces 20s may form a second corner portion 20c. The second shielding structures SC2 may be paired, and the pair of the second shielding structure SC2 may be adjacent to each other based on the second corner portion 20c. For example, the first shielding structures SC1 and the second shielding structures SC2 may be provided in four units adjacent to each of the first corner portions 10c and the second corner portions 20c, respectively.

The first shielding structures SC1 and the second shielding structures SC2 may include a first metal material and a second metal material. The first metal material may include at least one of silver or copper. The second metal material may be tin. In this case, in the first shielding structures SC1 and the second shielding structures SC2, a content of the first metal material may be greater than a content of the second metal material. For example, in the first shielding structures SC1 and the second shielding structures SC2, the content of the first metal material may be about 70 wt % to about 97 wt %, and the content of the second metal material may be about 3 wt % to about 30 wt %. The content of the first metal material and the second metal material may be a content measured based on 100 wt % of each of the first shielding structures SC1 and the second shielding structures SC2.

As silver and copper contents are higher than tin contents, melting points of the first shielding structures SC1 and the second shielding structures SC2 may be higher than melting points of the second connection terminals 490 and the third connection terminals 480. The melting points of the first shielding structures SC1 and the second shielding structures SC2 may be, for example, about 500° C. or higher.

A second molding layer 590 may be provided to cover an upper surface of the interposer substrate 150, a side surface of the first semiconductor chip 10, a side surface of the first molding layer 440, and side surfaces of the second underfill layer UF2 and the third underfill layer UF3. The second molding layer 590 may include an insulating material such as an epoxy molding compound (EMC).

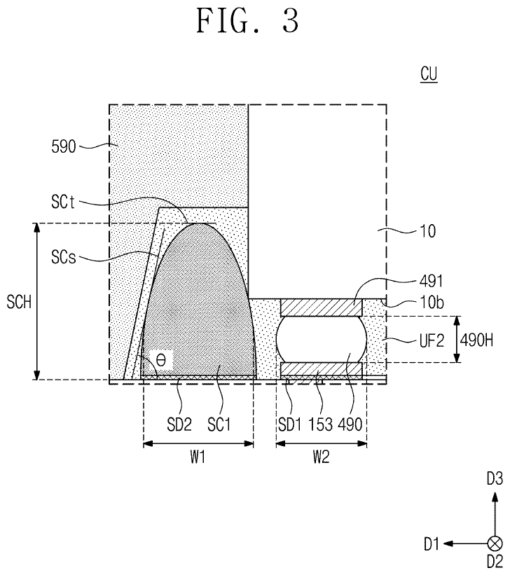

FIG. 3 is an enlarged view of portion ‘CU’ of FIG. 2. Specifically, FIG. 3 is an enlarged view of the first shielding structure SC1, but the features related to the shape and size of the first shielding structure SC1 may be substantially equally applied to the second shielding structure SC2. The description overlapping with FIG. 1 and FIG. 2 will be omitted.

Referring to FIG. 2 and FIG. 3, the first shielding structure SC1 according to an example embodiment of the inventive concepts may have a shape protruding from the upper surface of the interposer substrate 150. A first seed pattern SD1 may be provided on a lower surface of the upper interposer pad 153. A second seed pattern SD2 may be provided on a lower surface of the first shielding structure SC1.

A height SCH of the first shielding structure SC1 may be greater than a height 490H of the second connection terminals 490. The height SCH of the first shielding structure SC1 may be, for example, about 30 μm to about 500 μm. A level of an upper surface SCt of the first shielding structure SC1 may be positioned between a lower surface 10b of the first semiconductor chip 10 and an upper surface 10a of the first semiconductor chip 10. A level of the upper surface of the second shielding structure SC2 may also be positioned between a lower surface of the second semiconductor chip 410 and an upper surface of the second semiconductor chip 410.

The first shielding structure SC1 may have a first width W1 in the first direction D1. The second connection terminal 490 may have a second width W2 in the first direction D1. The first width W1 may be larger than the second width W2.

The first width W1 may decrease in the third direction D3 away from the interposer substrate 150. The first width W1 may be, for example, about 100 μm to about 500 μm.

Both side surfaces of the first shielding structure SC1 may have inclined portions SCs. The inclined portion SCs of the first shielding structure SC1 may in contact with the first semiconductor chip 10. An angle θ of the inclined portion SCs of the first shielding structures SC1 may be about 30° to about 60°. In the present specification, the angle θ of the inclined portion SCs of the first shielding structures SC1 may be an angle formed by a tangent line between the upper surface of the interposer substrate 150 and the side surface of the first shielding structure SC1.

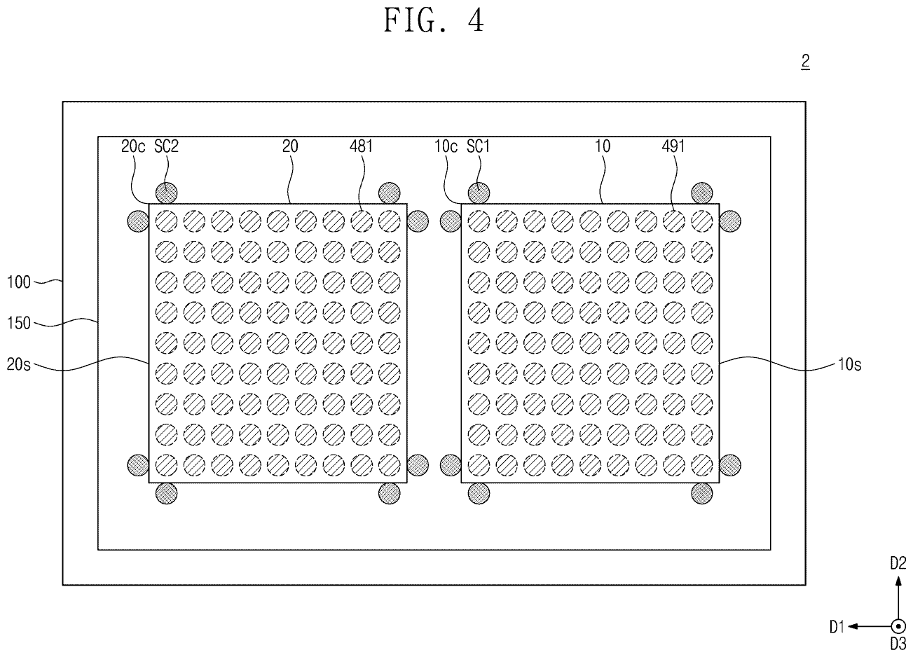

FIG. 4 is a plan view of a semiconductor package according to an example embodiment of the inventive concepts. Any description overlapping with FIGS. 1 to 3 will be omitted.

Referring to FIG. 4, a semiconductor package 2 according to an example embodiment of the inventive concepts may be provided with eight first shielding structures SC1 and eight second shielding structures SC2. Specifically, the first shielding structures SC1 may be paired, and the pair first shielding structures SC1 may be disposed adjacent to the first corners 10c of the first semiconductor chip 10, respectively. The second shielding structures SC2 may be paired, and the pair second shielding structures SC2 may be disposed adjacent to the second corners 20c of a chip structure 20, respectively. According to some example embodiments of the inventive concepts, the number of the first shielding structures SC1 and the second shielding structures SC2 may not be limited to those illustrated. Depending on example embodiments, the number of first shielding structures SC1 and second shielding structures SC2 may be 4 to 8.

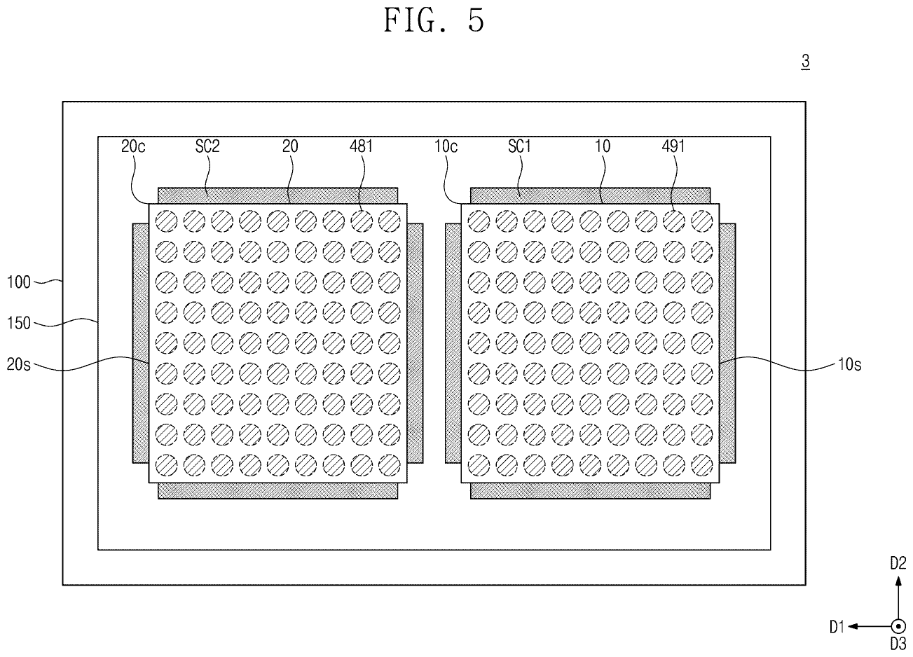

FIG. 5 is a plan view of a semiconductor package according to an example embodiment of the inventive concepts. Any description overlapping with FIGS. 1 to 3 will be omitted.

Referring to FIG. 5, the first shielding structure SC1 and the second shielding structure SC2 of a semiconductor package 3 according to an example embodiment of the inventive concepts may have a line shape extending in a direction parallel to the upper surface of the package substrate 100.

For example, some of the first shielding structures SC1 may have a line shape extending in the first direction D1, and the others may have a line shape extending in the second direction D2. In this case, one end of the first shielding structures SC1 may be adjacent to the first corner portion 10c.

Some of the second shielding structures SC2 may have a line shape extending in the first direction D1, and the remaining some of the second shielding structures SC2 may have a line shape extending in the second direction D2. In this case, one end of the second shielding structures SC2 may be adjacent to the second corner portion 20c.

The semiconductor package according to an example embodiment of the inventive concepts may include the shielding structure disposed on the side surface of the semiconductor chip on the interposer substrate. The shielding structure may have the inclined portion that is in contact with the semiconductor chip, and the level of the upper surface of the shielding structure may be higher than the level of the lower surface of the semiconductor chip. Accordingly, even when the impact is applied from the outside of the semiconductor package, the inclined portion of the shielding structure may block or prevent the position of the semiconductor chip from changing. In other words, as the semiconductor chip is blocked or prevented from slipping on the interposer substrate, structural stability of the semiconductor package may be improved.

In addition, the melting point of the shielding structures may be higher than the melting point of the connection terminals disposed between the interposer substrate and the lower surface of the semiconductor chip. Thus, even when a reflow process is performed on the connection terminals, the shape of the inclined portion, etc., of the shielding structures may be maintained, and thus the semiconductor chip may be stably positioned on the interposer substrate.

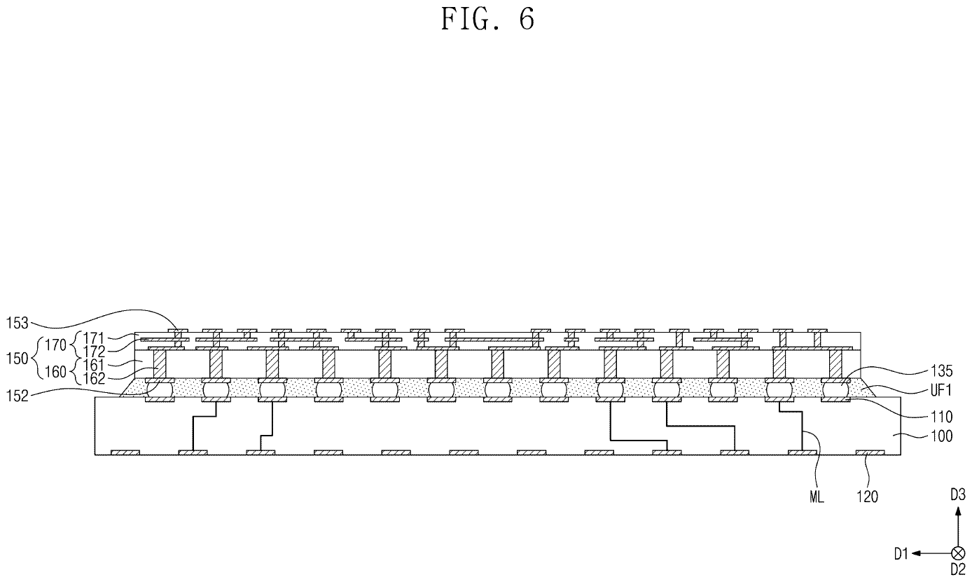

FIGS. 6, 7, 8, 9, and 10 are cross-sectional views illustrating a manufacturing process of a semiconductor package according to an example embodiment of the inventive concepts.

Referring to FIG. 6, an interposer substrate 150 may be provided on a package substrate 100. The package substrate 100 may include a plurality of first substrate pads 110 on an upper surface, a plurality of second substrate pads 120 on a lower surface, and metal wirings ML.

The interposer substrate 150 may include an interposer core layer 160 and an interposer wiring layer 170. The interposer core layer 160 may include a core substrate 161 and interposer vias 162. The interposer wiring layer 170 may include an interposer insulating layer 171 and wiring patterns 172 in the interposer insulating layer 171. Upper interposer pads 153 may be disposed on an upper surface of the interposer substrate 150. Lower interposer pads 152 may be disposed on a lower surface of the interposer substrate 150.

A first underfill layer UF1 may be provided between the package substrate 100 and the interposer substrate 150 to surround the first connection terminals 135 and side surfaces of the first connection terminals 135.

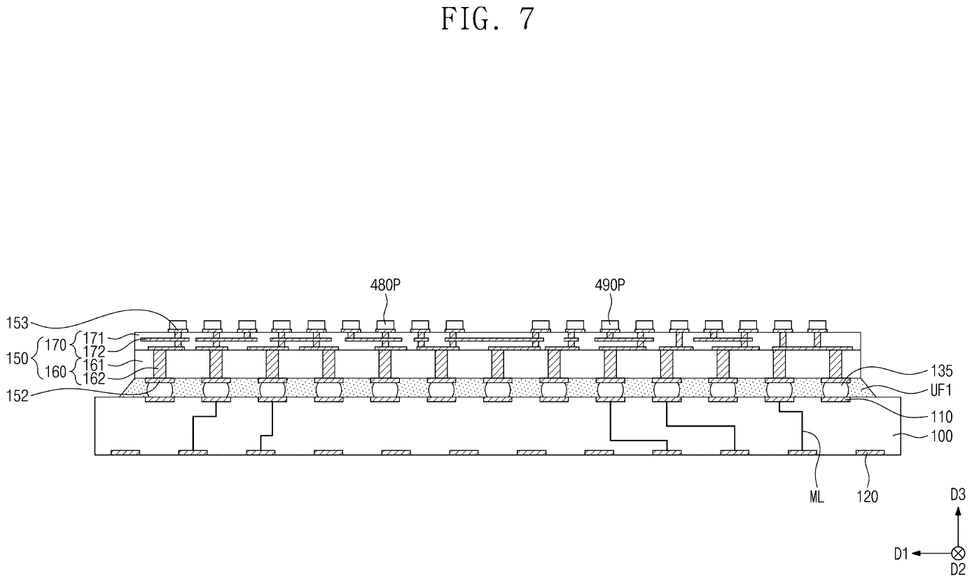

Referring to FIG. 7, second preliminary connection terminals 490P and third preliminary connection terminals 480P may be formed on upper interposer pads 153. The second preliminary connection terminals 490P and third preliminary connection terminals 480P may be spaced apart in the first direction D1.

Forming the second preliminary connection terminals 490P and third preliminary connection terminals 480P may include forming a mask pattern on the interposer substrate 150 that exposes a space where a seed pattern and the second preliminary connection terminals 490P and the third preliminary connection terminals 480P are to be formed, performing an electroplating process using the seed pattern as an electrode through an exposed portion of the mask pattern, and removing the mask pattern.

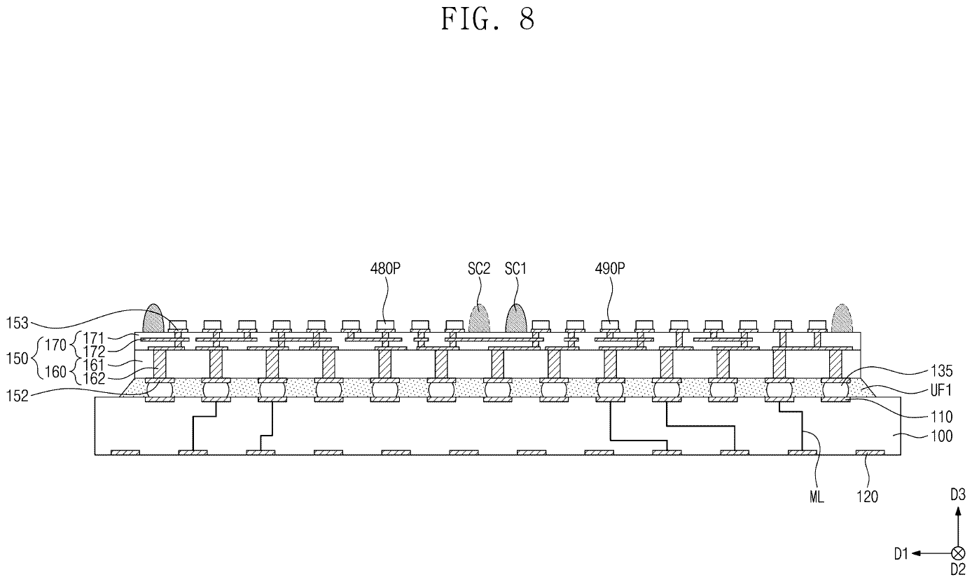

Referring to FIG. 8, first shielding structures SC1 and second shielding structures SC2 may be formed on an interposer substrate 150. The first shielding structures SC1 and second shielding structures SC2 may be spaced apart in the first direction D1.

Forming the first shielding structures SC1 and second shielding structures SC2 may include forming a mask pattern that exposes a space where a seed pattern and the first shielding structures SC1 and second shielding structures SC2 are to be formed on the interposer substrate 150, performing an electroplating process using the seed pattern as an electrode through an exposed portion of the mask pattern, and removing the mask pattern.

The first shielding structures SC1 and the second shielding structures SC2 may have different metal contents from those the second preliminary connection terminals 490P and the third preliminary connection terminals 480P. For example, the first shielding structures SC1 and the second shielding structures SC2 may have a higher content of silver and copper than a content of tin, compared to the second preliminary connection terminals 490P and the third preliminary connection terminals 480P. For example, in the first shielding structures SC1 and the second shielding structures SC2, the content of silver and copper may be about 70 wt % to about 97 wt %, and the content of tin may be about 3 wt % to about 30 wt %.

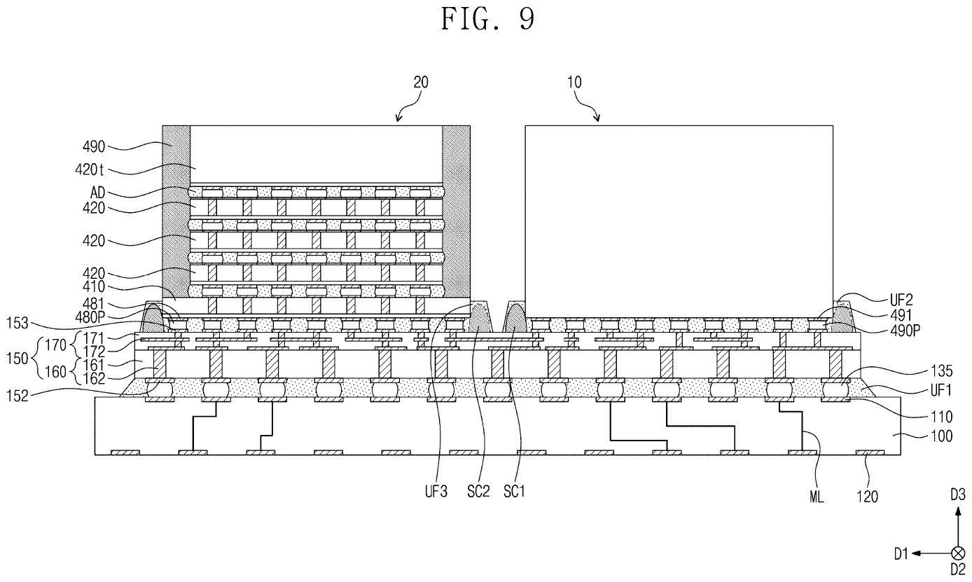

Referring to FIG. 9, a first semiconductor chip 10 and a chip structure 20 may be mounted on an interposer substrate 150. The chip structure 20 may include a second semiconductor chip 410, third semiconductor chips 420 and 420t disposed on the second semiconductor chip 410, adhesive layers AD, and a first molding layer 440.

For example, mounting the first semiconductor chip 10 may include performing first chip pads 491 on a lower surface of the first semiconductor chip 10 coming in contact with second preliminary connection terminals 490P. Mounting the chip structure 20 may include performing second chip pads 481 on the lower surface of the chip structure 20 coming in contact with third preliminary connection terminals 480P.

Thereafter, a second underfill layer UF2 may be formed in a space between the first semiconductor chip 10 and the interposer substrate 150. A third underfill layer UF3 may be formed in a space between the chip structure 20 and the interposer substrate 150.

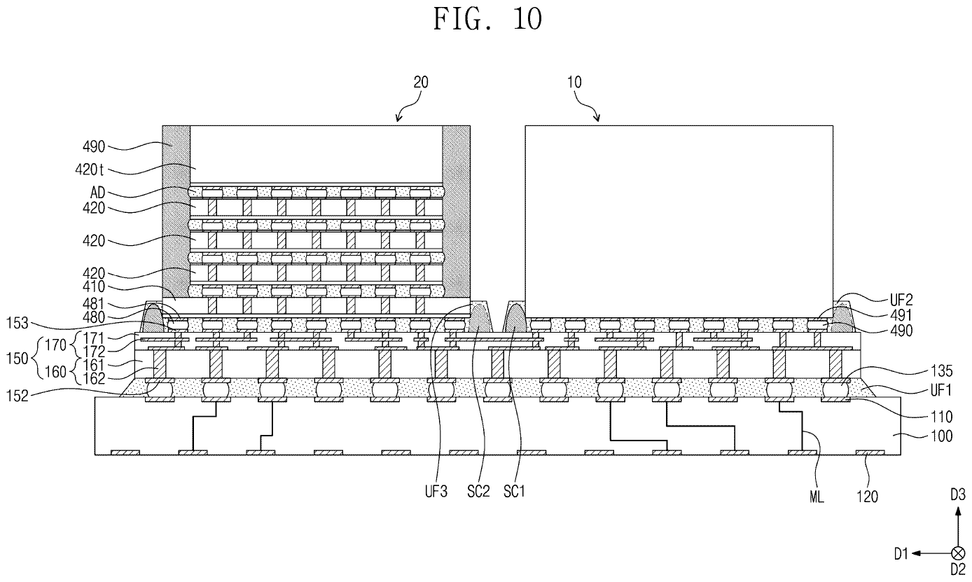

Referring to FIG. 10, a reflow process may be performed on the second preliminary connection terminals 490P and the third preliminary connection terminals 480P. The reflow process may be performed at a temperature higher than the melting point of the second preliminary connection terminals 490P and the third preliminary connection terminals 480P.

For example, the reflow process may be performed at about 200° C. to about 260° C. Due to the reflow process, shapes of the second preliminary connection terminals 490P and the third preliminary connection terminals 480P may become close to a spherical shape. As a result of performing the reflow process, the second connection terminals 490 and the third connection terminals 480 may be formed from the second preliminary connection terminals 490P and the third preliminary connection terminals 480P, respectively.

In this case of the first shielding structure SC1 and the second shielding structure SC2, the content of silver and copper may be higher than the content of tin, the melting point increases, and thus the shape thereof may not be deformed even when the reflow process is performed.

Referring again to FIG. 2, a second molding layer 590 may be formed on the upper surface of the interposer substrate 150, and then external connection terminals 130 may be attached on the second substrate pads 120 disposed on the lower surface of the package substrate 100, thereby completing the semiconductor package according to the example embodiment of the inventive concepts.

According to an example embodiment of the inventive concepts, the semiconductor package may include the shielding structure on the side surface of the semiconductor chip on the interposer substrate. The shielding structure may have the inclined portion that is in contact with the semiconductor chip, and the inclined portion may be in contact with the semiconductor chip. Accordingly, even when the impact is applied from the outside of the semiconductor package, the inclined portion of the shielding structure may block or prevent the position of the semiconductor chip from changing. Thus, the structural stability of the semiconductor package may be improved.

While some example embodiments are described above, a person skilled in the art may understand that many modifications and variations are made without departing from the spirit and scope of the inventive concepts defined in the following claims. Accordingly, the above example embodiments of the inventive concepts should be considered in all respects as illustrative and not restrictive, with the spirit and scope of the inventive concepts being indicated by the appended claims.

What is claimed is:

1. A semiconductor package comprising:
a substrate;
a semiconductor chip and a shielding structure on the substrate; and
a connection terminal between the substrate and the semiconductor chip,
wherein the shielding structure is on a side surface of the semiconductor chip,
wherein a level of an upper surface of the shielding structure is between a lower surface of the semiconductor chip and an upper surface of the semiconductor chip, and
wherein a melting point of the shielding structure is higher than a melting point of the connection terminal.

2. The semiconductor package of claim 1, wherein the melting point of the shielding structure is 500° C. or higher.

3. The semiconductor package of claim 1, wherein
the shielding structure includes a first metal material and a second metal material,
the first metal material includes at least one of silver or copper,
the second metal material is tin, and
a content of the first metal material is greater than a content of the second metal material, in the shielding structure.

4. The semiconductor package of claim 3, wherein
the content of the first metal material is 70 wt % to 97 wt % based on 100 wt % of the shielding structure, and
the content of the second metal material is 3 wt % to 30 wt % based on 100 wt % of the shielding structure.

5. The semiconductor package of claim 1, wherein a height of the shielding structure is 30 μm to 500 μm.

6. The semiconductor package of claim 1, wherein
the shielding structure has a first width in a first direction parallel to an upper surface of the substrate, and
the first width decreases in a second direction perpendicular to the upper surface of the substrate.

7. The semiconductor package of claim 6, wherein
the connection terminal has a second width in the first direction, and
the first width is larger than the second width.

8. The semiconductor package of claim 6, wherein the first width of the shielding structure is 100 μm to 500 μm.

9. The semiconductor package of claim 1, further comprising:
an underfill layer between the substrate and the semiconductor chip,
wherein the shielding structure is in contact with the underfill layer.

10. A semiconductor package comprising:
a substrate; and
a semiconductor chip and a plurality of shielding structures on the substrate,
wherein the semiconductor chip has four side surfaces connected to each other, and two adjacent side surfaces of the four side surfaces form corner portions,
wherein a side surface of each of the shielding structures have an inclined portion, and
wherein the shielding structures are at least one pair, and the pair of the shielding structures is adjacent to each other based on the corner portion.

11. The semiconductor package of claim 10, wherein an angle of the inclined portion of each of the shielding structures is 30° to 60°.

12. The semiconductor package of claim 10, wherein the inclined portion of each of the shielding structures is in contact with the semiconductor chip.

13. The semiconductor package of claim 10, wherein a number of the shielding structures is 4 to 8.

14. The semiconductor package of claim 10, wherein the shielding structures have a line shape extending in a direction parallel to an upper surface of the substrate, when viewed in a plan view.

15. A semiconductor package comprising:
a package substrate;
an interposer substrate on the package substrate;
a chip stack, a semiconductor chip, and first and second shielding structures on the interposer substrate; and
connection terminals between the interposer substrate and the chip stack and between the interposer substrate and the semiconductor chip,
wherein the semiconductor chip and the chip stack are spaced apart in a first direction parallel to an upper surface of the package substrate,
wherein the first shielding structure is on a side surface of the chip stack,
wherein the second shielding structure is on a side surface of the semiconductor chip,
wherein a height of the first and second shielding structures is greater than a height of the connection terminals,
wherein the first and second shielding structures include a first metal material and a second metal material,
wherein the first metal material includes at least one of silver or copper,
wherein the second metal material is tin,
wherein, in the first and second shielding structures, a content of the first metal material is 70 wt % to 97 wt % based on 100 wt % of the first and second shielding structures, and
wherein a content of the second metal material is 3 wt % to 30 wt % based on 100 wt % of the first and second shielding structures.

16. The semiconductor package of claim 15, further comprising:
a first underfill layer between the interposer substrate and the chip stack, and covering side surfaces of the connection terminals,
a second underfill layer between the interposer substrate and the semiconductor chip, and covering side surfaces of the connection terminals,
wherein the first shielding structure is in contact with the first underfill layer, and
wherein the second shielding structure is in contact with the second underfill layer.

17. The semiconductor package of claim 15, wherein a height of the first and second shielding structures are 30 μm to 500 μm.

18. The semiconductor package of claim 15, wherein a melting point of the first and second shielding structures is 500° C. or higher.

19. The semiconductor package of claim 15, wherein
the interposer substrate further includes an interposer pad on an upper surface of the interposer substrate, and
the first and second shielding structures are spaced apart from the interposer pad in the first direction.

20. The semiconductor package of claim 15, wherein
the first and second shielding structures each have a shape protruding from an upper surface of the interposer substrate, and
a width of the first and second shielding structures in the first direction is 100 μm to 500 μm.
